(19) United States
(12) Patent Application Publication
(10) Pub. No.: US 2025/0331166 A1
(43) Pub. Date: Oct. 23, 2025

(54) SEMICONDUCTOR DEVICE HAVING BIT LINE STRUCTURE AND METHOD FOR MANUFACTURING THE SAME

(71) Applicant: NANYA TECHNOLOGY CORPORATION, NEW TAIPEI CITY (TW)

(72) Inventor: CHUN-HENG WU, NEW TAIPEI CITY (TW)

(21) Appl. No.: 18/664,653

(22) Filed: May 15, 2024

Related U.S. Application Data
(62) Division of application No. 18/640,236, filed on Apr. 19, 2024.

(51) Int. Cl. H10B 12/00

(52) U.S. Cl. CPC H10B 12/482

(57) ABSTRACT

A semiconductor device and a method of manufacturing a semiconductor device are provided. The semiconductor device includes a substrate having a first recess region, and a first bit line structure in the first recess region. The first bit line structure has a first spacer, a second spacer, and a third spacer. The first spacer, the second spacer, and the third spacer have different materials.

### CROSS-REFERENCE TO RELATED APPLICATION

This application is a divisional application of U.S. Non-Provisional application Ser. No. 18/640,236 filed Apr. 19, 2024, which is incorporated herein by reference in its entirety.

### TECHNICAL FIELD

The present disclosure relates to a semiconductor device and a method for manufacturing a semiconductor device, and more particularly, to a bit line structure having a spacer.

### DISCUSSION OF THE BACKGROUND

In a semiconductor device, a storage node contact may be formed between neighboring bit line structures. In a conventional process, a recess region may be formed adjacent to a bit line structure and a material of a storage node contact may fill the recess region. A spacer of the bit line structure may inevitably be consumed in the operation of forming the recess region, potentially increasing the likelihood of a bit line structure to storage node contact leakage issue. Said leakage issue can cause performance deterioration of the semiconductor device, and is a limiting factor that must be addressed to achieve further enhancements in semiconductor device integration.

In addition, as semiconductor devices become more highly integrated, the distance between the bit line structures and/or the distance between the bit line structure and the storage node contact is diminishing, which may increase the probability of a significant parasitic capacitance issue.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a substrate having a first recess region, and a first bit line structure in the first recess region. The first bit line structure has a first spacer, a second spacer, and a third spacer. The first spacer, the second spacer, and the third spacer have different materials.

Another aspect of the present disclosure provides a semiconductor device. The semiconductor device includes a substrate and a first bit line structure disposed over the substrate. The first bit line structure has a first spacer continuously disposed on a sidewall of the first bit line structure and fill a space between the first bit line structure and the substrate.

Another aspect of the present disclosure provides a method of manufacturing a semiconductor device. The method includes forming a first recess region in a substrate, forming a bit line structure in the first recess region, and disposing a first spacer in the recess region. The method also includes performing a surface treatment on the first spacer and partially removing the first spacer.

The first spacer can prevent the first bit line structure from being damaged or consumed. Therefore, the bit line structure to storage node contact leakage issue can be addressed. The performance and operational reliability of the semiconductor device can also be improved.

In addition, by using a spacer having a low dielectric constant, the parasitic capacitance issue between the bit line structures and/or between the bit line structure and the storage node contact can be further reduced.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1A is a schematic cross-sectional view of a semiconductor device in accordance with some embodiments of the present disclosure.

FIG. 1B is a schematic cross-sectional view of a semiconductor device in accordance with some embodiments of the present disclosure.

FIG. 1C is a schematic cross-sectional view of a semiconductor device in accordance with some embodiments of the present disclosure.

FIG. 2A is a schematic plan view illustrating one or more stages of a method of manufacturing a semiconductor device in accordance with some embodiments of the present disclosure.

FIG. 2B is a schematic cross-sectional view illustrating the semiconductor device taken along an A-A′ line shown in FIG. 2A.

FIG. 2C is a schematic cross-sectional view illustrating the semiconductor device taken along a B-B′ line shown in FIG. 2A.

FIG. 3A is a schematic plan view illustrating one or more stages of a method of manufacturing a semiconductor device in accordance with some embodiments of the present disclosure.

FIG. 3B is a schematic cross-sectional view illustrating the semiconductor device taken along an A-A′ line shown in FIG. 3A.

FIG. 4A is a schematic plan view illustrating one or more stages of a method of manufacturing a semiconductor device in accordance with some embodiments of the present disclosure.

FIG. 4B is a schematic cross-sectional view illustrating the semiconductor device taken along an A-A′ line shown in FIG. 4A.

FIG. 4C is a schematic cross-sectional view illustrating the semiconductor device taken along a B-B′ line shown in FIG. 4A.

FIG. 5A is a schematic cross-sectional view illustrating one or more stages of a method of manufacturing a semiconductor device in accordance with some embodiments of the present disclosure.

FIG. 5B is a schematic cross-sectional view illustrating one or more stages of a method of manufacturing a semiconductor device in accordance with some embodiments of the present disclosure.

FIG. 6A is a schematic cross-sectional view illustrating one or more stages of a method of manufacturing a semiconductor device in accordance with some embodiments of the present disclosure.

FIG. 6B is a schematic cross-sectional view illustrating one or more stages of a method of manufacturing a semiconductor device in accordance with some embodiments of the present disclosure.

FIG. 7A is a schematic cross-sectional view illustrating one or more stages of a method of manufacturing a semiconductor device in accordance with some embodiments of the present disclosure.

FIG. 7B is a schematic cross-sectional view illustrating one or more stages of a method of manufacturing a semiconductor device in accordance with some embodiments of the present disclosure.

FIG. 8A is a schematic cross-sectional view illustrating one or more stages of a method of manufacturing a semiconductor device in accordance with some embodiments of the present disclosure.

FIG. 8B is a schematic cross-sectional view illustrating one or more stages of a method of manufacturing a semiconductor device in accordance with some embodiments of the present disclosure.

FIG. 9A is a schematic cross-sectional view illustrating one or more stages of a method of manufacturing a semiconductor device in accordance with some embodiments of the present disclosure.

FIG. 9B is a schematic cross-sectional view illustrating one or more stages of a method of manufacturing a semiconductor device in accordance with some embodiments of the present disclosure.

FIG. 10A is a schematic cross-sectional view illustrating one or more stages of a method of manufacturing a semiconductor device in accordance with some embodiments of the present disclosure.

FIG. 10B is a schematic cross-sectional view illustrating one or more stages of a method of manufacturing a semiconductor device in accordance with some embodiments of the present disclosure.

FIG. 11 is a schematic cross-sectional view illustrating one or more stages of a method of manufacturing a semiconductor device in accordance with some embodiments of the present disclosure.

FIG. 12 is a schematic cross-sectional view illustrating one or more stages of a method of manufacturing a semiconductor device in accordance with some embodiments of the present disclosure.

FIG. 13 illustrates a flow chart of a method of manufacturing a semiconductor device in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only, and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

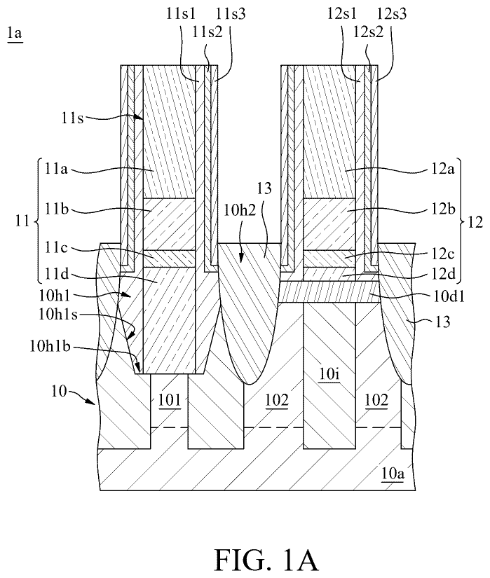

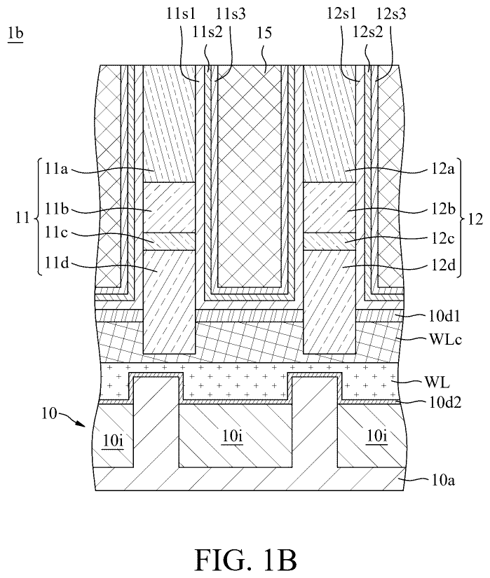

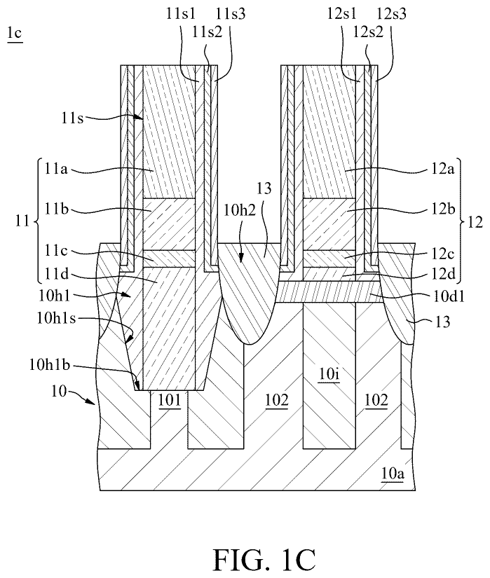

FIG. 1A is a schematic cross-sectional view of a semiconductor device la in accordance with some embodiments of the present disclosure. In some embodiments, the semiconductor device la may be disposed adjacent to a circuit. For example, the semiconductor device la may be disposed adjacent to a memory device such as a dynamic random access memory (DRAM) device or the like.

Referring to FIG. 1A, the semiconductor device la may include a substrate 10 and bit line structures 11 and 12. The bit line structures 11 and 12 may be disposed over the substrate 10.

The substrate 10 may include a semiconductor substrate. In some embodiments, the semiconductor material of the substrate 10 may include, for example, silicon (Si) (such as monocrystalline silicon, polysilicon, and amorphous silicon), germanium (Ge), gallium (Ga), and indium (In). In some embodiments, the semiconductor material of the substrate 10 may include a compound semiconductor including silicon germanium (SiGe), silicon carbide (SiC), silicon germanium carbide (SiGeC), gallium arsenide (GaAs), gallium phosphide (GaP), indium arsenide (InAs), indium phosphide (InP), indium antimonide (InSb), or other IV-IV, III-V or II-VI semiconductor materials.

In some embodiments, the substrate 10 may include a bulk semiconductor, a semiconductor-on-insulator (SOI) substrate, a multi-layered substrate, or a gradient substrate. For example, the SOI substrate may include a layer of a semiconductor material formed on an insulator layer. The insulator layer may be, for example, a buried oxide (BOX) layer, a silicon oxide layer, or the like. The insulator layer may be provided on a substrate, typically a silicon or glass substrate. In some embodiments, the substrate 10 may be a wafer, such as a silicon wafer. The substrate 10 may be doped (e.g., with a P-type or an N-type dopant) or undoped.

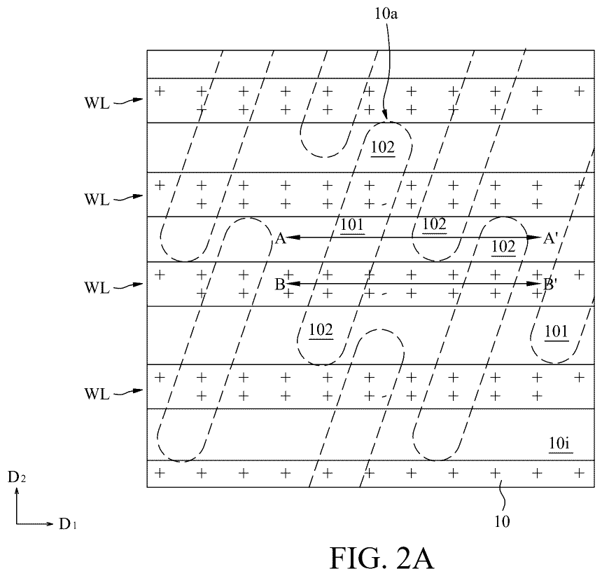

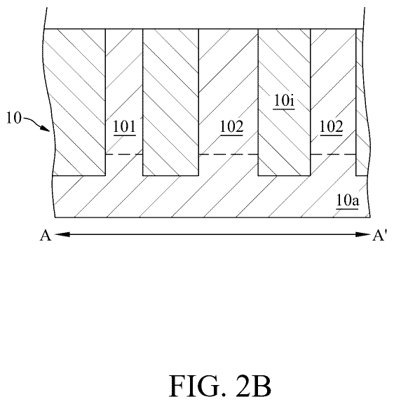

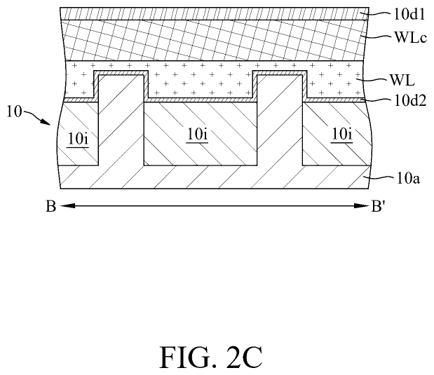

From the cross-sectional view shown in FIG. 1A, the substrate 10 may include an active region 10a and a plurality of isolation regions 10i. From the top view shown in FIG. 2A, a plurality of the active regions 10a may be defined by the isolation region 10i. For example, a plurality of the active regions 10a may be separated from one another by the isolation region 10i.

The active region 10a and the isolation region 10i may be formed in the substrate 10. In some embodiments, the isolation region 10i may include shallow trench isolation (STI) structures.

A wall oxide, a liner and a gap-fill dielectric may be sequentially formed as the isolation region 10i. The liner may be formed by stacking silicon oxide (SiO₂) and silicon nitride (Si₃N₄). The gap-fill dielectric may include, for example, silicon oxide (SiO₂), silicon nitride (Si₃N₄), a low-k (e.g., having a dielectric constant less than that of silicon oxide, which is about 3.9) dielectric material (e.g., phosphosilicate glass (PSG), borosilicate glass (BSG), boron-doped phosphosilicate glass (BPSG), undoped silicate glass (USG), etc.), the like, or combinations thereof. In another embodiment, in the isolation region 10i, a silicon nitride may be used as the gap-fill dielectric.

The substrate 10 may include a plurality of doped regions, such as a first doped region 101 and second doped regions 102. The first doped region 101 and the second doped regions 102 may be formed in the active region 10a. In some embodiments, the first doped region 101 and the second doped regions 102 may be disposed over or proximal to the top surface of the active region 10a. The first doped region 101 and the second doped regions 102 may be spaced apart from one another by the isolation regions 10i. From the top view shown in FIG. 2A, the first doped region 101 and the second doped region 102 may be located on opposite sides of one of the word lines WL.

In some embodiments, the first doped region 101 and the second doped region 102 may be doped with an N-type dopant such as phosphorus (P), arsenic (As), or antimony (Sb). In some other embodiments, the first doped region 101 and the second doped region 102 may be doped with a P-type dopant such as boron (B) or indium (In). In some embodiments, the first doped region 101 and the second doped region 102 may be doped with dopants or impurity ions having the same conductivity types. In some embodiments, the first doped region 101 and the second doped region 102 may be doped with dopants or impurity ions having different conductivity types.

The bottom surfaces of the first doped region 101 and the second doped region 102 may be located at a predetermined depth from the top surface of the active region 10a. The first doped region 101 and the second doped region 102 may be adjacent to sidewalls of the isolation region 10i. The bottom surfaces of the first doped region 101 and the second doped region 102 may be higher than the bottom surface of the isolation region 10i.

In some embodiments, the first doped region 101 and the second doped region 102 may be referred to as source/drain regions. In some embodiments, the first doped region 101 may include a bit line contact region and may be electrically connected with the bit line structure 11. The second doped region 102 may include a storage node contact region and may be electrically connected with a memory element through the storage node contact 13. In some embodiments, the memory element may be a capacitor, and may include a lower electrode, an upper electrode and a dielectric layer therebetween. In other embodiments, the memory element may be a variable resistance pattern capable of switching between two resistance states by an electrical pulse applied to the memory element. For example, the memory element may include a phase change material capable of changing a crystalline state according to an amount of electrical current, such as perovskite compounds, transition metal oxide, magnetic materials, ferromagnetic materials or antiferromagnetic materials.

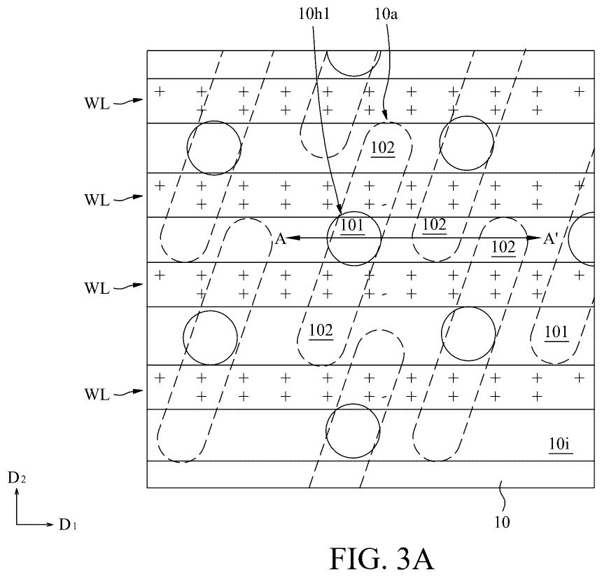

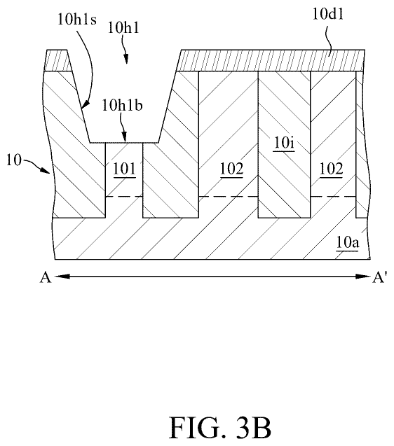

An interlayer 10d1 may be disposed on the substrate 10. The interlayer 10d1 may be disposed on the top surface of the active region 10a. The interlayer 10d1 may be formed of either a single insulating layer or a plurality of insulating layers. The interlayer 10d1 may include an isolating material or a dielectric material. The interlayer 10d1 may include, for example, silicon oxide (SiO₂), silicon nitride (Si₃N₄) and/or silicon oxynitride. The interlayer 10d1 may define the bit line contact region, as shown in FIG. 3B.

A recess region 10h1 may be formed in the substrate 10. The bit line structure 11 may be disposed in the recess region 10h1 and contact (such as directly contact) the first doped region 101. Therefore, the first doped region 101 may include the bit line contact region.

The recess region 10h1 may be formed between the isolation regions 10i. The recess region 10h1 may be formed to expose the first doped region 101 between the isolation regions 10i.

The recess region 10h1 may recess into the substrate 10 from the top surface of the active region 10a and/or from the interlayer 10d1. The recess region 10h1 may have a sidewall 10h1s and a bottom surface 10h1b. The sidewall 10h1s may extend from the bottom surface 10h 1b to the top surface of the active region 10a and/or the interlayer 10d1.

The sidewall 10h1s of the recess region 10h1 may be inclined with respect to the top surface of the active region 10a and/or the interlayer 10d1. The recess region 10h1 may narrow or taper toward the interior of the substrate 10. The width of the recess region 10h1 may vary. For example, the width of the recess region 10h1 adjacent to the top surface of the active region 10a may be greater than the width of the recess region 10h1 adjacent to the bottom surface 10h1b. The minimum width of the recess region 10h1 may be the width of the bottom surface 10h1b of the recess region 10h1.

The width of the bottom surface 10h1b of the recess region 10h1 may be greater than the distance between the isolation regions 10i. The minimum width of the bottom surface 10h1b of the recess region 10h1 may be greater than the width of the bit line structure 11. For example, the bottom surface of the bit line structure 11 may contact the exposed surfaces of the doped region 101 and the isolation regions 10i.

The bottom surface 10h1b of the recess region 10h1 may be positioned higher than the bottom surface of the first doped region 101. For example, the recess region 10h1 may not extend beyond the bottom surface of the first doped region 101.

A recess region 10h2 may be formed in the substrate 10 to expose the second doped region 102. The second doped region 102 may contact the storage node contact 13. Therefore, the second doped region 102 may include the storage node contact region.

The recess region 10h2 may recess from the top surface of the active region 10a and/or from the interlayer 10d1. The recess region 10h2 may be adjacent to the recess region 10h1.

The storage node contact 13 may be formed of, for example, a doped polysilicon layer and may penetrate the interlayer 10d1 to contact (such as directly contact) the second doped region 102.

The bottom surface of the storage node contact 13 may be positioned lower than the bottom surface 10h1b of the recess region 10h1.

The bit line structure 11 may include a bit line contact 11d and stacked patterns (such as a conductive pattern 11c, a conductive pattern 11b, and a bit line capping pattern 11a).

The bit line contact 11d may be disposed in the recess region 10h1. A portion of the bit line contact 11d may contact (such as directly contact) the first doped region 101. A bottom surface of the bit line contact 11d may be positioned lower than the top surface of the active region 10a or lower than the interlayer 10d1. The bit line contact 11d may include a doped polysilicon.

The conductive pattern 11c may include any suitable material, such as titanium (Ti), tantalum (Ta), titanium nitride (TiN), tantalum nitride (TaN), tungsten nitride (W₂N, WN, WN₂), the like, or combinations thereof.

The conductive pattern 11b may include any suitable metal, such as tungsten (W), copper (Cu), ruthenium (Ru), aluminum (Al), gold (Au), cobalt (Co), the like, or combinations thereof.

The bit line capping pattern 11a may include, for example, silicon oxide (SiO₂), silicon nitride (Si₃N₄) and/or silicon oxynitride.

The bit line structure 11 may include spacers 11s1, 11s2, and 11s3 formed on both sidewalls 11s of the bit line structure 11. The spacers 11s1, 11s2, and 11s3 may also be referred to as a first spacer, a second spacer, and a third spacer. The spacer 11s1 may be disposed between the spacer 11s2 and the sidewalls 11s of the bit line structure 11. For example, the spacer 11s1 may directly contact the sidewalls of the bit line structure 11. The spacer 11s2 may be disposed between the spacer 11s1 and the spacer 11s3. The spacer 11s3 may be the outermost spacer of the bit line structure 11.

The spacers 11s1, 11s2, and 11s3 may have different materials. In some embodiments, the spacer 11s1 may include a carbon-containing material, such as SiC (silicon carbide), SiOC (silicon oxycarbide), SiCN (silicon carbon nitride), and SiOCN (silicon oxycarbonitride). The spacer 11s2 may include an oxygen-containing material, such as silicon oxide (SiO₂). The spacer 11s3 may include a nitrogen-containing material, such as silicon nitride (Si₃N₄).

The spacers 11s1, 11s2, and 11s3 may have different dielectric constants. In some embodiments, the spacer 11s1 may have a first dielectric constant, the spacer 11s2 may have a second dielectric constant, and the spacer 11s3 may have a third dielectric constant.

The first dielectric constant may be lower than the second dielectric constant. The second dielectric constant may be lower than the third dielectric constant. For example, the third dielectric constant may be approximately 7.5, and the second dielectric constant may be less than approximately 7.5. For example, the second dielectric constant may be approximately 3.9, and the first dielectric constant may be less than approximately 3.9. For example, the first dielectric constant may range from approximately 1.0 to 3.9. In some embodiments, the spacer 11s1 may include a low-k material.

The spacer 11s1 may have a thickness of approximately 10 nanometers (nm) or less. In an embodiment, the spacer 11s1 may have a thickness of from approximately 5 nm to approximately 8 nm.

The spacer 11s1 may be continuously disposed on sidewalls of the bit line structure 11. For example, the spacer 11s1 may contact (such as directly contact) the bit line capping pattern 11a, the conductive pattern 11b, the conductive pattern 11c, and the bit line contact 11d. The spacer 11s1 may be disposed in the recess region 10h1. The spacer 11s1 may fill the space between the bit line structure 11 and the substrate 10. The spacer 11s1 may fill the space between the bit line structure 11 and the isolation regions 10i.

The spacer 11s1 may extend between the sidewall 10h1s and the bit line contact 11d. The spacer 11s1 may contact (such as directly contact) the sidewall 10h1s and the bottom surface 10h1b of the recess region 10h1. In some embodiments, there may be no other material other than the spacer 11s1 existing between the sidewall 10h1s and the bit line contact 11d.

In some embodiments, the storage node contact 13 may truncate the sidewall 10h1s and the spacer 11s1 may contact (such as directly contact) the storage node contact 13.

The bit line structure 12 may be spaced apart from (or separated from) the bit line structure 11 by the storage node contact 13. The bit line structure 12 may be disposed over the interlayer 10d1. The bit line structure 12 may be spaced apart from (or separated from) the substrate 10 by the interlayer 10d1.

The bit line structure 12 may include a bit line contact 12d and stacked patterns (such as a conductive pattern 12c, a conductive pattern 12b, and a bit line capping pattern 12a). The bit line structure 12 may include spacers 12s1, 12s2, and 12s3 formed on both sidewalls of the bit line structure 12. The detailed descriptions of the bit line structure 12 may refer to detailed descriptions of the bit line structure 11 provided above, which will not be repeated for the sake of brevity.

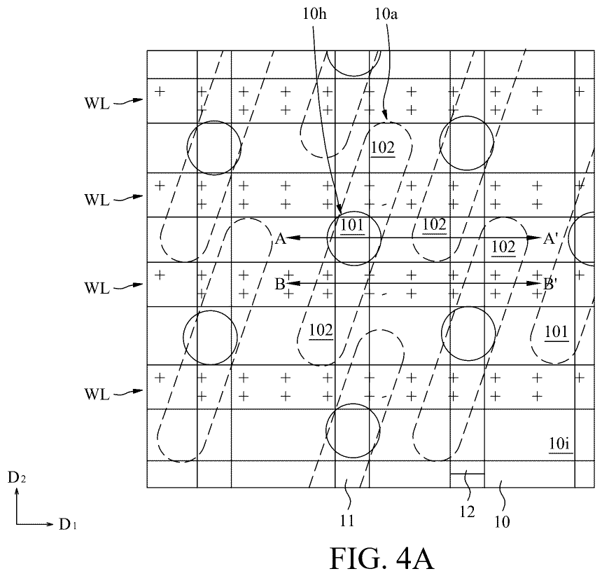

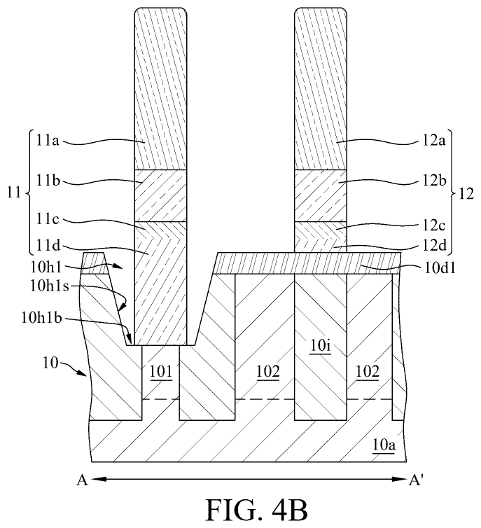

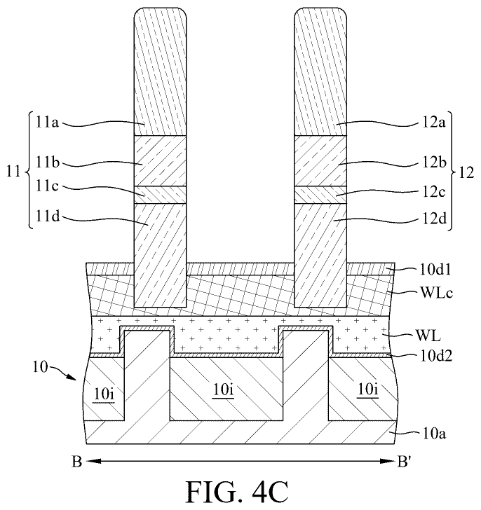

FIG. 1B is a schematic cross-sectional view of a semiconductor device 1b in accordance with some embodiments of the present disclosure. FIG. 1A illustrates a cross-sectional view taken along lines A-A′ of FIG. 4A and FIG. 1B illustrates a cross-sectional view taken along lines B-B′ of FIG. 4A. The semiconductor device 1b of FIG. 1B is similar to the semiconductor device 1a of FIG. 1A, except for the differences described below.

The active region 10a may protrude more than the isolation region 10i. A dielectric layer 10d2 may be conformally formed on the active region 10a and the isolation region 10i.

The word line WL may be disposed over the dielectric layer 10d2. The word line WL may include a gate electrode. The word line WL may extend through the active regions 10a and the isolation region 10i. A capping layer WLc of the word-line WL may be disposed on the gate electrode of the word line WL. The capping layer WLc may serve to protect the gate electrode of the word line WL.

The bit line contact 11d of the bit line structure 11 may be partially surrounded by the capping layer WLc. The bit line contact 12d of the bit line structure 12 may be partially surrounded by the capping layer WLc.

The spacer 11s1 and the spacer 12s1 may be connected. For example, the spacer 11s1 and the spacer 12s1 may extend between the bit line structure 11 and the bit line structure 12. For example, the carbon-containing materials of the spacer 11s1 and the spacer 12s1 may extend between the bit line structure 11 and the bit line structure 12.

The spacer 11s2 and the spacer 12s2 may be connected. For example, the spacer 11s2 and the spacer 12s2 may extend between the bit line structure 11 and the bit line structure 12. For example, the oxygen-containing materials of the spacer 11s2 and the spacer 12s2 may extend between the bit line structure 11 and the bit line structure 12.

The spacer 11s3 and the spacer 12s3 may be connected. For example, the spacer 11s3 and the spacer 12s3 may extend between the bit line structure 11 and the bit line structure 12. For example, the nitrogen-containing materials of the spacer 11s3 and the spacer 12s3 may extend between the bit line structure 11 and the bit line structure 12.

An insulating pattern 15 may be formed between the bit line structure 11 and the bit line structure 12. For example, the insulating pattern 15 may be disposed over the spacer 11s3 and the spacer 12s3.

FIG. 1C is a schematic cross-sectional view of a semiconductor device 1c in accordance with some embodiments of the present disclosure. The semiconductor device 1c of FIG. 1C is similar to the semiconductor device la of FIG. 1A, except that the bottom surface of the storage node contact 13 may be positioned higher than the bottom surface 10h1b of the recess region 10h1 with respect to the substrate 10. For example, the bottom surface 10h1b of the recess region 10h1 may be positioned lower than the bottom surface of the storage node contact 13 with respect to the substrate 10. For example, the bottom surface (at the same elevation of the bottom surface 10h1b) of the bit line structure 11 may be positioned lower than the bottom surface of the storage node contact 13 with respect to the substrate 10.

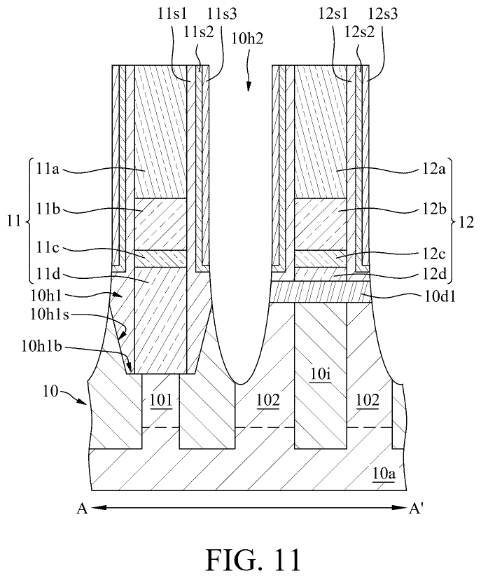

In a conventional process, a recess region (such as the recess region 10h2) may be formed adjacent to a bit line structure (such as the bit line structure 11), and a material of a storage node contact (such as the storage node contact 13) may fill the recess region. A spacer (such as the spacers 11s1, 11s2, and 11s3) of the bit line structure may inevitably be consumed in the operation of forming the recess region (such as the operation in FIG. 11), which in turn may increase the likelihood of a bit line structure to storage node contact leakage issue. Said leakage issue can cause performance deterioration of the semiconductor device, and is a limiting factor that must be addressed to achieve further enhancements in semiconductor device integration.

The first spacer (such as the spacer 11s1) can prevent the first bit line structure (such as the bit line structure 11) from being damaged or consumed. Therefore, the bit line structure to storage node contact leakage issue can be addressed. The performance and operational reliability of the semiconductor device can also be improved.

In addition, by using a spacer (such as the spacer 11s1) having a low dielectric constant, the parasitic capacitance issue between the bit line structures and/or between the bit line structure and the storage node contact can be further decreased.

FIGS. 2A, 2B, 2C, 3A, 3B, 4A, 4B, 4C, 5A, 5B, 6A, 6B, 7A, 7B, 8A, 8B, 9A, 9B, 10A, 10B, 11 and 12 illustrate stages of a method of manufacturing a semiconductor device in accordance with some embodiments of the present disclosure. At least some of these figures have been simplified for a better understanding of the aspects of the present disclosure. In some embodiments, the semiconductor device la in FIG. 1A may be manufactured by the operations described below with respect to FIGS. 2A, 2B, 2C, 3A, 3B, 4A, 4B, 4C, 5A, 5B, 6A, 6B, 7A, 7B, 8A, 8B, 9A, 9B, 10A, 10B, 11 and 12.

As shown in FIG. 2A, the semiconductor device may include a plurality of active regions 10a. The active regions 10a may be arranged in a zigzag form. For example, the active regions 10a may be two-dimensionally arranged along a first direction DI and a second direction D2 intersecting or crossing (e.g., perpendicular to) the first direction D1. The active regions 10a may have a major axis oblique to the first direction D1 and the second direction D2.

The isolation region 10i may be formed through an STI (shallow trench isolation) process. For example, after a pad layer (not shown) is formed on the substrate 10, the pad layer and the substrate 10 are etched using an isolation mask (not shown) to define an isolation trench. The isolation trench is filled with a dielectric material, and accordingly, the isolation region 10i is formed.

The isolation trench may be filled with a dielectric material through a chemical vapor deposition (CVD) process. Also, a planarization process such as chemical-mechanical polishing (CMP) may be additionally performed.

The semiconductor device may also include a plurality of word lines WL. Each active region 10a may cross two word lines WL and may be divided into three doped regions by the two word lines WL. For example, the active region 10a may be divided into the first doped region 101 disposed between two word lines WL and the second doped regions 102 located at two sides of the first doped region 101.

The word lines WL may each have a line shape extending in any one direction, such as the first direction D1. The word lines WL may each be a buried gate buried in a trench that runs through the active regions 10a and the isolation region 10i.

FIG. 2B illustrates a cross-sectional view taken along lines A-A′ of FIG. 2A, and FIG. 2C illustrates a cross-sectional view taken along lines B-B′ of FIG. 2A.

As shown in FIG. 2B, the first doped region 101 and two second doped regions 102 may be formed in the active region 10a. The first doped region 101 and two second doped regions 102 may be spaced apart from one another by the isolation regions 10i. As shown in FIG. 2C, the dielectric layer 10d2 may be disposed between the word line WL and the active region 10a, and between the word line WL and the isolation regions 10i. The active region 10a may protrude into the word line WL. The active region 10a may form a fin structure with respect to the isolation regions 10i.

As shown in FIG. 3A, one or more recess regions may be formed in the substrate 10. For example, the recess region 10h1 may be formed in the first doped region 101 between two word lines WL. In some embodiments, the substrate 10 may be patterned to form one or more recess regions exposing the first doped region 101. In some embodiments, the substrate 10 may be patterned to form one or more recess regions exposing the bit line contact region in the first doped region 101, and the bit line contact region is configured to be electrically connected with a bit line structure.

In some embodiments, the recess regions may be arranged in either a honeycomb form or a zigzag form in a top view. In some embodiments, the recess regions may each have a circular shape or an elliptical shape.

FIG. 3B illustrates a cross-sectional view taken along lines A-A′ of FIG. 3A. The interlayer 10d1 may be disposed on the substrate 10. The interlayer 10d1 may be disposed on the top surface of the active region 10a.

In some embodiments, the recess region 10h1 may be formed by an etching operation, such as an anisotropic etching operation. For example, the interlayer 10d1 may define the first doped region 101 or the bit line contact region in the first doped region 101.

In some embodiments, a portion of the isolation regions 10i and a portion of the interlayer 10d1 that are adjacent to the first doped region 101 may be etched together. For example, the sidewall 10h1s may be inclined with respect to the top surface of the active region 10a and/or the interlayer 10d1. The recess region 10h1 may narrow or taper toward the interior of the substrate 10. A sidewall of the interlayer 10d1 may be substantially aligned with the sidewall 10h1s.

As shown in FIG. 4A, a plurality of bit line structures (such as the bit line structures 11 and 12) may be formed over the substrate 10.

The bit line structures may each have a line shape extending in a second direction D2 crossing the word lines WL. The bit line structures may each overlap a plurality of the recess regions. For example, the bit line structure 11 may overlap the recess region 10h1.

FIG. 4B illustrates a cross-sectional view taken along lines A-A′ of FIG. 4A. FIG. 4C illustrates a cross-sectional view taken along lines B-B′ of FIG. 4A.

As shown in FIG. 4B and FIG. 4C, the bit line structure 11 may include the bit line contact 11d for connecting the bit line contact region in the first doped region 101. The bit line structure 12 may include the bit line contact 12d disposed over the interlayer 10d1. The bit line structures may each include a bit line contact, a conductive pattern, a conductive pattern, and a bit line capping pattern that are sequentially stacked.

In some embodiments, the bit line structure 11 may be formed by disposing the material of the bit line contact 11d over the interlayer 10d1 to fill the recess region 10h1, and disposing the materials of the conductive pattern 11c, the conductive pattern 11b, and the bit line capping pattern 11a sequentially. Then, the materials may be etched through a bit line mask pattern.

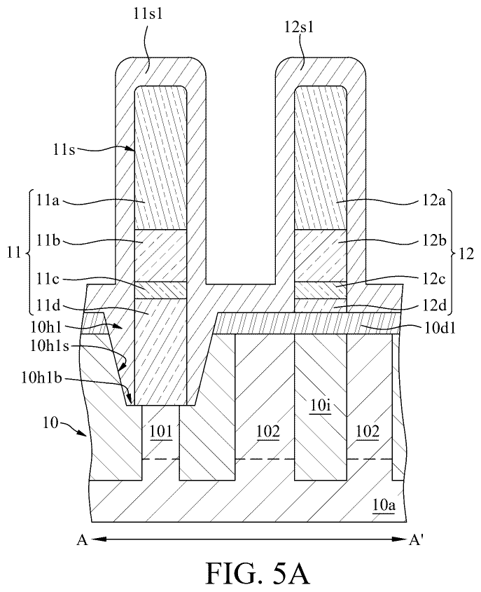

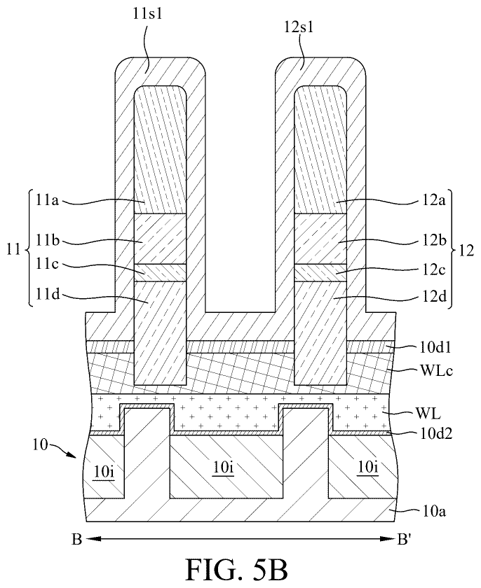

FIG. 5A and FIG. 5B illustrate operations subsequent to the operation in FIGS. 4A. FIG. 5A illustrates a cross-sectional view taken along lines A-A′ of FIG. 4A. FIG. 5B illustrates a cross-sectional view taken along lines B-B′ of FIG. 4A.

As shown in FIG. 5A and FIG. 5B, a material of the spacer 11s1 may be formed on opposite sidewalls 11s of the bit line structure 11. A material of the spacer 12s1 may be formed on opposite sidewalls 11s of the bit line structure 12. In some embodiments, the spacers 11s1 and 12s1 may each include a carbon-containing material, such as SiC (silicon carbide), SiOC (silicon oxycarbide), SiCN (silicon carbon nitride), and SiOCN (silicon oxycarbonitride). In some embodiments, the spacers 11s1 and 12s1 may be formed by any suitable process, such as low-pressure chemical vapor deposition (LPCVD), plasma enhanced-chemical vapor deposition (PECVD), atomic layer deposition (ALD), or physical vapor deposition (PVD), thermally grown, or chemically grown.

In some embodiments, the materials of the spacers 11s1 and 12s1 may fill the recess region 11h1 and conformally cover the bit line structures 11 and 12.

In some embodiments, a thickness of the material of the spacer 11s1 on the bit line structure 11 may range from approximately 15 nm to approximately 20 nm. In some embodiments, a thickness of the material of the spacer 12s1 on the bit line structure 12 may range from approximately 15 nm to approximately 20 nm.

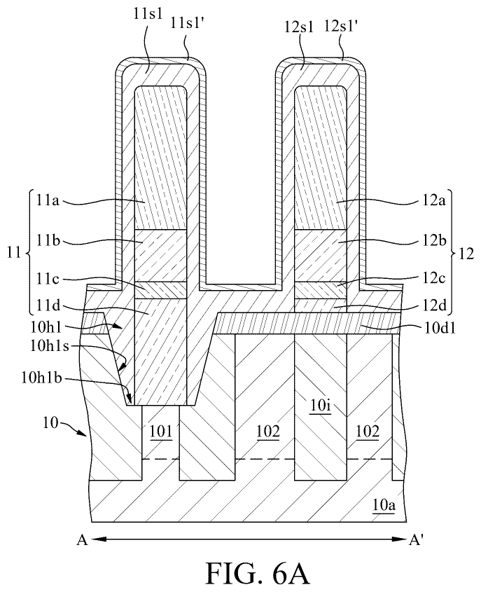

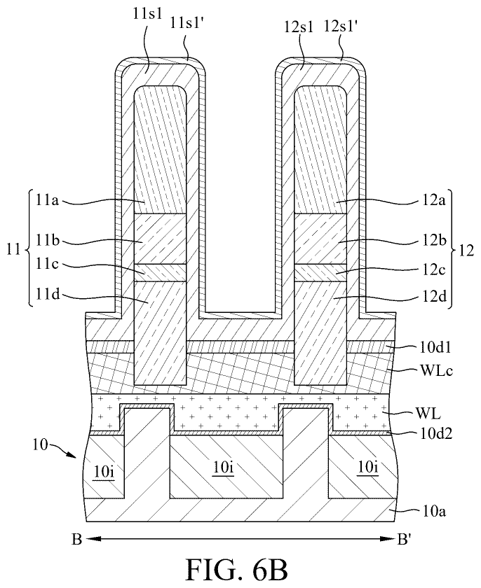

FIG. 6A and FIG. 6B illustrate operations subsequent to the operations in FIGS. 5A and 5B.

As shown in FIG. 6A and FIG. 6B, a surface treatment may be performed on the materials of the spacers 11s1 and 12s1 to change or modify the surface property of the materials of the spacers 11s1 and 12s1. For example, parts of the materials of the spacers 11s1 and 12s1 may be oxidized by oxygen plasma to enhance the etching rate of the surfaces of the materials of the spacers 11s1 and 12s1.

After the surface treatment, the treated materials (such as a treated material 11s1′ of the spacer 11s1 and a treated material 12s1′ of the spacer 12s1) may be formed.

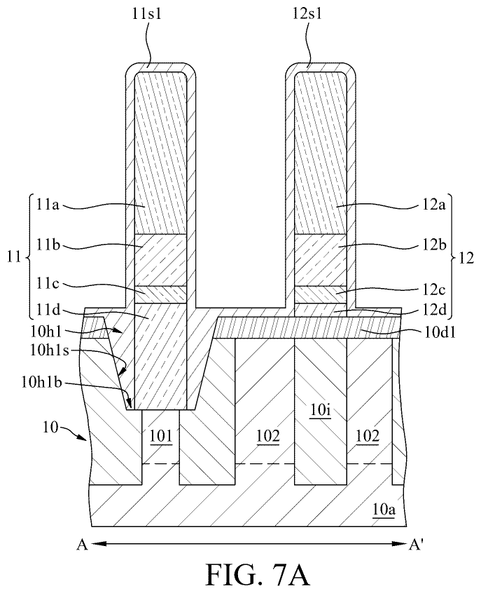

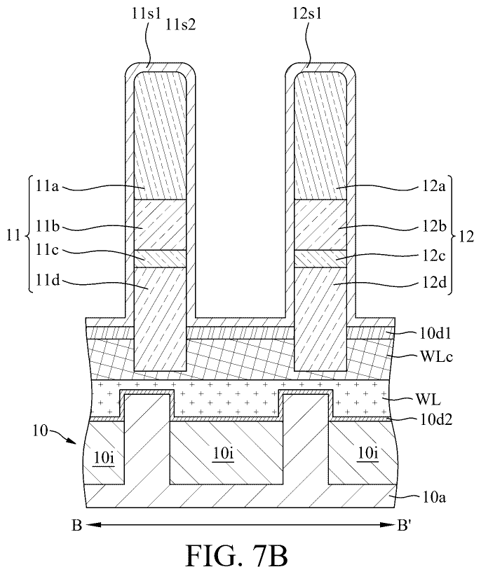

FIG. 7A and FIG. 7B illustrate operations subsequent to the operations in FIGS. 6A and 6B.

As shown in FIG. 7A and FIG. 7B, the treated materials (such as a treated material 11s1′ of the spacer 11s1 and a treated material 12s1′ of the spacer 12s1) may be removed by any suitable etching operation, such as a wet etching operation. After the etching operation, a thickness of the material of the spacer 11s1 on the bit line structure 11 may range from approximately 5 nm to approximately 8 nm, and a thickness of the material of the spacer 12s1 on the bit line structure 12 may range from approximately 5 nm to approximately 8 nm.

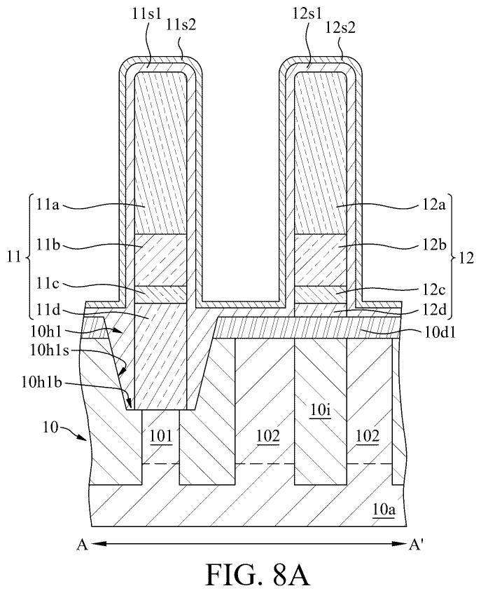

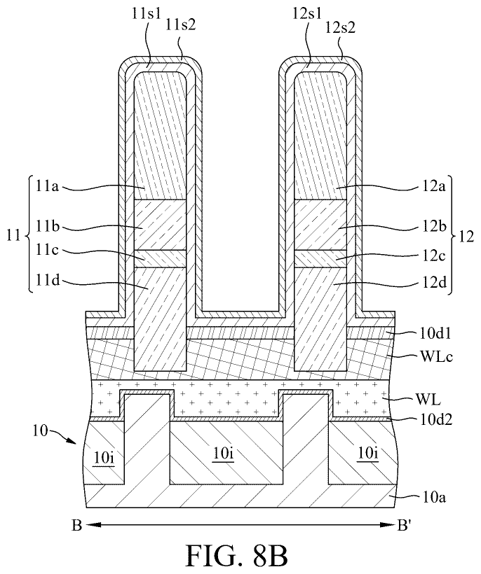

FIG. 8A and FIG. 8B illustrate operations subsequent to the operations in FIGS. 7A and 7B.

As shown in FIG. 8A and FIG. 8B, a material of the spacer 11s2 may be formed on opposite sidewalls of the bit line structure 11. A material of the spacer 12s2 may be formed on opposite sidewalls of the bit line structure 12. In some embodiments, the spacers 11s2 and 12s2 may each include an oxygen-containing material, such as silicon oxide (SiO₂). In some embodiments, the materials of the spacers 11s2 and 12s2 may be formed by any suitable process, such as atomic layer deposition (ALD).

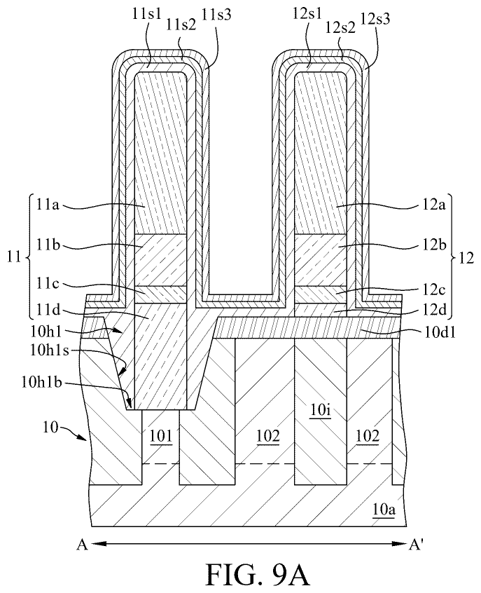

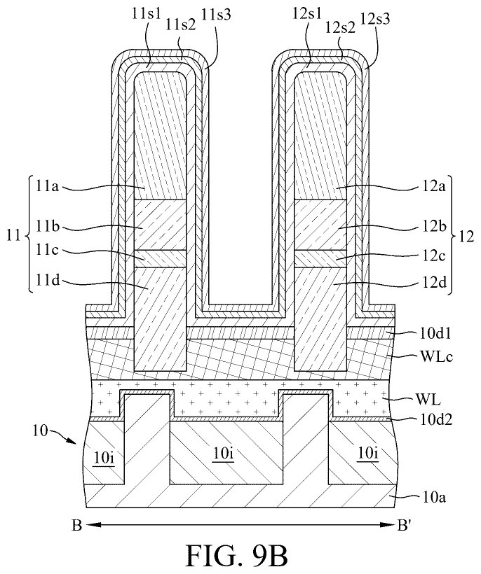

FIG. 9A and FIG. 9B illustrate operations subsequent to the operations in FIGS. 8A and 8B.

As shown in FIG. 9A and FIG. 9B, a material of the spacer 11s3 may be formed on opposite sidewalls of the bit line structure 11. A material of the spacer 12s3 may be formed on opposite sidewalls of the bit line structure 12. In some embodiments, the spacers 11s3 and 12s3 may each include a nitrogen-containing material, such as silicon nitride (Si₃N₄). In some embodiments, the materials of the spacers 11s3 and 12s3 may be formed by any suitable process, such as atomic layer deposition (ALD).

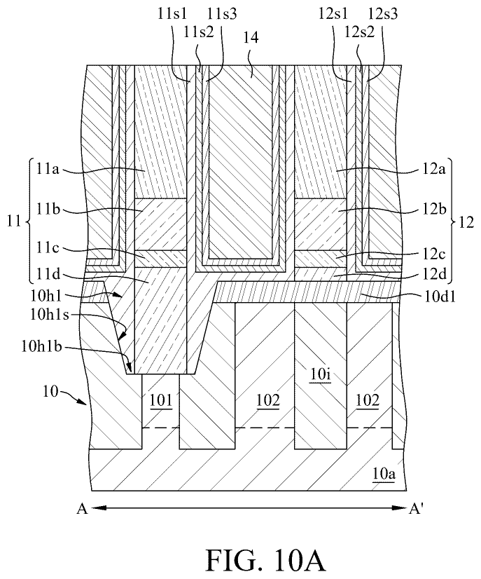

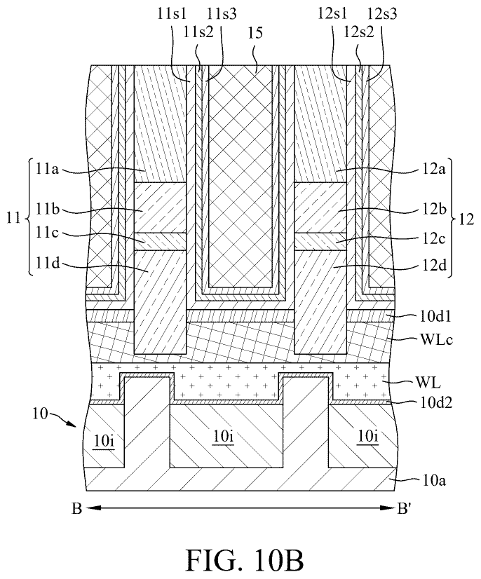

FIG. 10A and FIG. 10B illustrate operations subsequent to the operations in FIGS. 9A and 9B.

As shown in FIG. 10A, sacrificial patterns 14 may be formed among the plurality of bit line structures (such as the bit line structures 11 and 12). In a top view shown in FIG. 4A, the sacrificial patterns 14 may be spaced apart from each other in the second direction D2 and may be disposed between the word lines WL. The sacrificial patterns 14 may have an etching selectivity with respect to the materials of the spacers 11s3 and 12s3. For example, the sacrificial patterns 14 may have an etching rate higher than the materials of the spacers 11s3 and 12s3. For example, the sacrificial patterns 14 may be formed of a spin-on-hard mask (SOH) material (e.g., SOH silicon oxide).

As shown in FIG. 10B, insulating patterns 15 may be formed among the plurality of bit line structures (such as the bit line structures 11 and 12). In a top view shown in FIG. 4A, the insulating patterns 15 may fill a space defined by the plurality of bit line structures and the sacrificial patterns 14 and may overlap with the word lines WL. The insulating patterns 15 may include an insulating material having an etch selectivity with respect to the sacrificial patterns 14. For example, the insulating patterns 15 may include, for example, silicon oxide (SiO₂), silicon nitride (Si₃N₄) and/or silicon oxynitride.

In some embodiments, sacrificial patterns 14 and insulating patterns 15 may be formed alternately and may be arranged along the second direction D2 between the bit line structures.

In some embodiments, the formation of the sacrificial patterns 14 and the insulating patterns 15 may include forming a material of the sacrificial patterns 14 to fill between the bit line structures, forming mask patterns (which may extend parallel to the word lines WL in the first direction D1) over the material of the sacrificial patterns 14, anisotropically etching the material of the sacrificial patterns 14 using the mask patterns and the bit line structures as an etch mask to form the sacrificial patterns 14 exposing the word lines WL, forming a material of the insulating patterns 15 to fill spaces between the sacrificial patterns 14 and between the bit line structures, and planarizing the material of the insulating patterns 15 to expose top surfaces of the mask patterns.

FIG. 11 illustrates operations subsequent to the operations in FIGS. 10A and 10B. FIG. 11 illustrates a cross-sectional view taken along lines A-A′ of FIG. 4A.

As shown in FIG. 11, the sacrificial patterns 14 may be removed by using a suitable etching operation, such as a directional or anisotropic dry etching operation. After the etching operation, the recess region 10h2 may be formed in the substrate 10 to expose the second doped region 102.

During the etching operation, the spacer 11s1 may protect the bit line contact 11d from being etched, consumed or damaged. Therefore, the spacer 11s1 may serve as a protection layer or a passivation layer for the bit line contact 11d.

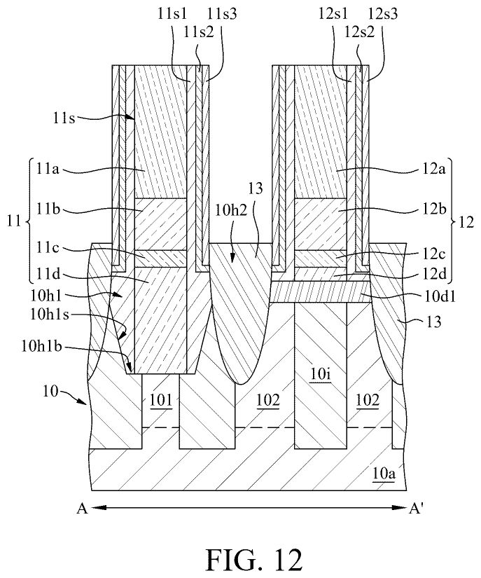

FIG. 12 illustrates operations subsequent to the operations in FIG. 11. FIG. 11 illustrates a cross-sectional view taken along lines A-A′ of FIG. 4A.

As shown in FIG. 12, a material of the storage node contact 13 may be disposed in the recess region 10h2. The material of the storage node contact 13 may be disposed adjacent to the bit line structure 11. Subsequently, a recessing process may be performed on the material of the storage node contact 13. The recessing process may be performed by a dry etch process, for example, an etch-back process.

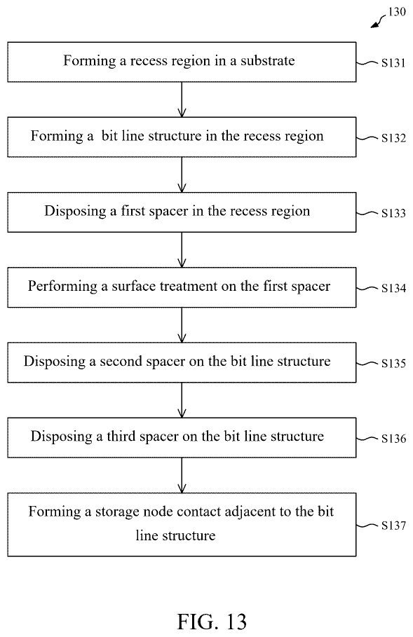

FIG. 13 illustrates a flow chart of a method 130 of manufacturing a semiconductor device in accordance with some embodiments of the present disclosure.

In some embodiments, the method 130 may include a step S131 of forming a recess region in a substrate. For example, as shown in FIG. 3A, the recess region 10h1 may be formed in the first doped region 101 between two word lines WL.

In some embodiments, the method 130 may include a step S132 of forming a bit line structure recess region in a substrate. For example, as shown in FIG. 4A, a plurality of bit line structures (such as the bit line structures 11 and 12) may be formed over the substrate 10.

In some embodiments, the method 130 may include a step S133 of disposing a first spacer in the recess region. For example, as shown in FIG. 5A, a material of the spacer 11s1 may be formed on opposite sidewalls 11s of the bit line structure 11. A material of the spacer 12s1 may be formed on opposite sidewalls 11s of the bit line structure 12. In some embodiments, the materials of the spacers 11s1 and 12s1 may fill the recess region 11h1 and conformally cover the bit line structures 11 and 12.

In some embodiments, the method 130 may include a step S134 of performing a surface treatment on the first spacer. For example, as shown in FIG. 6A, a surface treatment may be performed on the materials of the spacers 11s1 and 12s1 to change or modify the surface property of the materials of the spacers 11s1 and 12s1.

In some embodiments, the method 130 may include a step S135 of disposing a second spacer on the bit line structure. For example, as shown in FIG. 8A, a material of the spacer 11s2 may be formed on opposite sidewalls of the bit line structure 11. A material of the spacer 12s2 may be formed on opposite sidewalls of the bit line structure 12.

In some embodiments, the method 130 may include a step S136 of disposing a third spacer on the bit line structure. For example, as shown in FIG. 9A, a material of the spacer 11s3 may be formed on opposite sidewalls of the bit line structure 11. A material of the spacer 12s3 may be formed on opposite sidewalls of the bit line structure 12.

In some embodiments, the method 130 may include a step S137 of forming a storage node contact adjacent to the bit line structure. For example, as shown in FIG. 12, a material of the storage node contact 13 may be disposed in the recess region 10h2.

One aspect of the present disclosure provides a semiconductor device. The semiconductor device includes a substrate having a first recess region, and a first bit line structure in the first recess region. The first bit line structure has a first spacer, a second spacer, and a third spacer. The first spacer, the second spacer, and the third spacer have different materials.

Another aspect of the present disclosure provides a semiconductor device. The semiconductor device includes a substrate and a first bit line structure disposed over the substrate. The first bit line structure has a first spacer continuously disposed on a sidewall of the first bit line structure and fill a space between the first bit line structure and the substrate.

Another aspect of the present disclosure provides a method of manufacturing a semiconductor device. The method includes forming a first recess region in a substrate, forming a bit line structure in the first recess region, and disposing a first spacer in the recess region. The method also includes performing a surface treatment on the first spacer and partially removing the first spacer.

The first spacer can prevent the first bit line structure from being damaged or consumed. Therefore, the bit line structure to storage node contact leakage issue can be addressed. The performance and operational reliability of the semiconductor device can also be improved.

In addition, by using a spacer having a low dielectric constant, the parasitic capacitance issue between the bit line structures and/or between the bit line structure and the storage node contact can be further reduced.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a substrate; and
a first bit line structure disposed over the substrate;
wherein the first bit line structure has a first spacer continuously disposed on a sidewall of the first bit line structure and fill a space between the first bit line structure and the substrate.

2. The semiconductor device of claim 1, wherein the first spacer extends between the first bit line structure and the substrate.

3. The semiconductor device of claim 1, wherein the first bit line structure contacts a first doped region in the substrate.

4. The semiconductor device of claim 1, wherein the first spacer includes a carbon-containing material.

5. The semiconductor device of claim 1, further comprising:
a storage node contact disposed adjacent to the first bit line structure.

6. The semiconductor device of claim 5, wherein the first spacer contacts the storage node contact.

7. The semiconductor device of claim 5, wherein the storage node contact contacts a second doped region in the substrate.

8. The semiconductor device of claim 5, wherein a bottom surface of the first bit line structure is lower than the storage node contact with respect to the substrate.

9. The semiconductor device of claim 1, further comprising:
a second bit line structure disposed over the substrate, wherein the first spacer extends between the first bit line structure and the second bit line structure.

10. The semiconductor device of claim 9, wherein the second bit line structure is spaced apart from the substrate by an interlayer.

11. The semiconductor device of claim 1, wherein the first bit line structure has a second spacer continuously disposed over the first spacer.

12. The semiconductor device of claim 11, wherein the second spacer includes an oxygen-containing material.
